(19) United States
(12) Patent Application Publication
(10) Pub. No.: US 2007/0266303 A1
(43) Pub. Date: Nov. 15, 2007

(54) VITERBI DECODING APPARATUS AND TECHNIQUES

(75) Inventor: Garret Webster Shih, Brookline, MA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 11/740,808

(22) Filed: Apr. 26, 2007

Related U.S. Application Data
(60) Provisional application No. 60/795,848, filed on Apr. 27, 2006.

(51) Int. Cl. H03M 13/03

(52) U.S. Cl. 714/795

(57) ABSTRACT

Viterbi decoding techniques that include multi-stage Viterbi decoding of encoded signals. Such techniques include radix-4 two stage decoding. The encoded signals may include soft decision signals. A Viterbi decoder may include a branch metric generator, a trellis interconnect, an add-compare element, a path metric memory, and a traceback element. The add-compare element may include a plurality of add-compare-select units that each select two trace bits per clock cycle. The traceback element may write, decode, and trace stored trace bits to decode the encoded signal.

### CLAIM OF PRIORITY UNDER 35 U.S.C. §119

The present Application for Patent claims priority to Provisional Application No. 60/795,848 entitled “Viterbi Decoder, Radix-4 for a Wireless Communication Device” filed Apr. 27, 2006, assigned to the assignee hereof and hereby expressly incorporated by reference herein.

### BACKGROUND

1. Field

The present disclosure relates generally to decoding data signals and more particularly to Viterbi decoding data signals.

2. Background

In various communication processes, transmitted signals may be coded (e.g., bits of data may be transformed from a raw signal to a coded signal) for a variety of reasons and according to a variety of coding techniques. For example, some signals may be coded into a compressed signal to reduce bandwidth needed to transmit data. In another example, some signals may be coded into an error resistant signal to reduce a chance that a transmitted bit of data is incorrectly received at a destination.

Because wireless communication may be error prone, typical wireless communication uses an error reducing coding scheme. One traditional and well-known coding scheme used in wireless communication is convolution coding. Convolution coding transforms a series of m bit source signal into a n>m bit coded signal. The coding of each source bit is performed so that the coded bits corresponding to a source bit are based on a source bit and a number of preceding source bits. The source bit and preceding source bits are typically used as input in predetermined combinations to a series of modulo adders arranged according to a set of generator polynomials, the output of which results in the coded signal.

One well-known algorithm which is commonly used in wireless communication for decoding convolution encoded signals is known as the Viterbi algorithm. The Viterbi algorithm generally accepts an input of received coded signal values and generates a sequence of underlying states that a convolution encoder may have been in when generating the received coded signal. A decoded signal may then be generated by tracing the sequence of states in reverse order.

Traditional Viterbi decoders accept coded input signals corresponding to a single coded bit at each cycle and generate an output decoded signal based on the input signals. Such traditional Viterbi decoders may be referred to as single state Viterbi decoders because a single state transition in a trellis diagram is processed in each decoding cycle. As data rates increase, however, such Viterbi decoders may be unable to decode input signals fast enough even at high clock rates. For example, the IEEE 802.11n standard that implements multiple-input multiple-output wireless communication may operate at data rates around 360 megabytes per second. At clock rates of about 200 megahertz, traditional single state Viterbi decoders may be unable to decode an input signal to keep up with such data rates.

### SUMMARY

Techniques for Viterbi decoding a signal are disclosed herein. In one aspect of the instant disclosure, it is recognized that traditional single state Viterbi decoding techniques may be inadequate for Increased decoding throughput of modern technology such as the IEEE 802.11n developing standard. In another aspect of the instant disclosure, it is further recognized that multi-state Viterbi decoding techniques may be able to sustain increased throughput and reduce latency of traditional single state Viterbi decoding techniques.

One aspect of the instant disclosure includes a decoder apparatus. In some embodiments, the decoder apparatus includes an input element configured to receive a plurality of encoded input signals, and a multi-stage Viterbi decoder element configured to process the plurality of encoded input signals to determine a probable decoded signal.

In some embodiments, the multi-stage Viterbi decoder element includes a radix-4 two-stage Viterbi decoder element. In some embodiments, the plurality of encoded input signals includes four soft decision encoded input signals. In some embodiments, the multi-stage Viterbi decoder element comprises a branch metric element configured to determine a plurality of branch metrics, and an add-compare element configured to determine a plurality of current path metrics, and configured to output a plurality of pairs of current trace bits, each pair of trace bit corresponding to a respective one of the plurality of current path metrics.

In some embodiments, the add-compare element is configured to determine the plurality of current path metrics based on the plurality of branch metrics and a plurality of prior path metrics. In some embodiments, each current path metric represents a probability of a most-likely path to a respective current hypothesis state, the probability corresponding to a respective branch metric of the plurality of branch metrics and a respective prior path metric of the plurality of prior path metrics. In some embodiments, each prior path metric represents a probability of a most likely path to a respective previous hypothesis state corresponding to a prior set of received values of the plurality of encoded input signals.

In some embodiments, the add-compare element includes sixty-four add-compare units. In some embodiments, each add-compare unit is configured to process four branch metrics of the plurality of branch metrics and four prior path metrics of the plurality of prior path metrics. In some embodiments, each add-compare unit is configured to use a modulo-arithmetic add and compare to determine a respective current path metric of the plurality of current path metrics and a respective current hypothesis state of the plurality of current hypothesis states.

In some embodiments, the plurality of branch metrics includes a respective set of branch metrics for each set of received values of the plurality of encoded signals. In some embodiments, each respective set of branch metrics represents a set of probabilities that the current set of received values of the four soft decision encoded signals corresponds to a respective four hypothesis input signal values. In some embodiments, the branch metric element is configured to determine each respective set of branch metrics by processing a first and second received values of the current set of received values of the plurality of encoded signals separately from a third and fourth received values of the current set of received values of the plurality of encoded signals and then combining a first result of processing the first and second received values with a second result of processing the third and fourth received values.

In some embodiments, the first result includes four intermediate branch metrics, the second result includes four intermediate branch metrics, and each respective set of branch metrics includes sixteen branch metrics. In some embodiments, each branch metric of the plurality of branch metrics includes a five bit value.

In some embodiments, the multi-stage Viterbi decoder element comprises a trellis element configured to provide the add-compare element with the plurality of branch metrics, and a path metric element configured to store the plurality of current path metrics. In some embodiments, the add-compare element is configured to determine the plurality of current path metrics based on the plurality of branch metrics and a plurality of prior path metrics, and wherein the path metric element is configured to provide the add-compare element with the plurality of prior path metrics. In some embodiments, the path metric element is configured to store the plurality of current path metrics in a plurality of eight bit registers.

In some embodiments, the multi-stage Viterbi decoder element comprises a traceback element configured to store the plurality of pairs of current trace bits and pairs of previously determined trace bits corresponding to prior sets of received values of the plurality of input signals, and configured to determine the probable decoded signal based, at least in part, on the stored current and previously determined trace bits. In some embodiments, the traceback element is configured to determine a sequence of hypothesis states based, at least in part, on the stored current and previously determined hypothesis state values, and to determine a set of values of the probable decoded signal based on the sequence of hypothesis states.

In some embodiments, the traceback element is configured to determine the sequence of hypothesis states by selecting a most likely hypothesis state corresponding to each respective set of received values of the plurality of encoded signals in an order from the latest state to the earliest state. In some embodiments, the traceback element is configured to determine the set of values of the probable decoded signal by determining input values of a convolution algorithm that correspond to the sequence of hypothesis states. In some embodiments, the traceback element comprises four memory elements, and the traceback element is configured to use each memory element of the four memory elements to perform at least one of a decode operation, an idle operation, a write operation, and a decode operation

In some embodiments, each of the encoded input signals include a portion of a convolution coded signal and the probable decoded signal includes a decoding of the convolution coded signal. In some embodiments, the input element is configured to receive the plurality of encoded input signals from a wireless transmitter. In some embodiments, the plurality of convolution coded signals includes a signal encoded with a convolution coding constraint of seven. In some embodiments, a MIMO OFDM receiver apparatus comprises a decoder apparatus.

One aspect of the instant disclosure includes a decoder. In some embodiments, the decoder includes an input element configured to receive a plurality of encoded input signals, and a means for determining a probable decoded signal by performing a multi-stage Viterbi decoding process on the plurality of encoded input signals.

In some embodiments, the means for determining a probable decoded signal comprises a means for determining a plurality of branch metrics, each branch metric representing a probability that current received values of the four soft decision encoded input signals correspond to a respective four hypothesis input signal values, a means for determining a plurality of current path metrics based on the plurality of branch metrics and a plurality of prior path metrics, each current path metric representing a probability of a most likely path to a respective hypothesis current state corresponding to a set of current received values of the four soft decision encoded signals, and a means for determining a plurality of current trace bits, each corresponding to a respective one of the plurality of current path metrics and the current set of received values of the four soft decision encoded signals.

In some embodiments, the means for determining a probable decoded signal comprises a means for providing the means for determining a plurality of current path metrics with the plurality of branch metrics, a means for storing the plurality of current path metrics, and a means for providing the means for determining a plurality of current path metrics with the plurality of prior path metrics, each prior path metric representing a probability of a most likely path to a respective previous hypothesis state corresponding to a prior set of received values of the plurality of encoded input signals.

In some embodiments, the means for determining a probable decoded signal comprises a means for storing the current hypothesis state value for each of the plurality of current path metrics and a plurality of pairs of previously determined trace bits corresponding to previously received values of the encoded input signals, and a means for determining the probable decoded signal based, at least in part, on the stored current and previously determined trace bits.

In some embodiments, the means for determining the probable decoded signal comprises a means for determining a sequence of hypothesis states based, at least in part, on the stored hypothesis state values, and a means for determining a set of values of the probable decoded signal based on the sequence of hypothesis states.

In some embodiments, the means for determining the probable decoded signal comprises a means for determining the sequence of hypothesis states by selecting a most likely hypothesis state corresponding to each respective set of received values of the plurality of encoded signals in an order from the latest state to the earliest state. In some embodiments, the multi-stage Viterbi decoding process includes a two-stage Radix-4 Viterbi decoding process. In some embodiments, the plurality of encoded input signals includes four soft decision input signals.

One aspect of the instant disclosure includes a method of decoding an encoded input. In some embodiments, the method comprises receiving a plurality of encoded input signals, and performing a multi-stage Viterbi decoding on the plurality of soft decision encoded input signals to determine a probable decoded signal.

In some embodiments, Viterbi decoding comprises determining a plurality of branch metrics, determining a plurality of current path metrics, and determining a plurality of pairs of current trace bits, each corresponding to a respective one of the plurality of current path metrics. In some embodiments, determining the plurality of current path metrics comprises determining the plurality of current path metrics based on the plurality of branch metrics and a plurality of prior path metrics. In some embodiments, each current path metric represents a probability of a most-likely path to a respective current hypothesis state, the probability corresponding to a respective branch metric of the plurality of branch metrics and a respective prior path metric of the plurality of prior path metrics.

In some embodiments, each prior path metric represents a probability of a most likely path to a respective previous hypothesis state corresponding to a prior set of received values of the plurality of encoded input signals. In some embodiments, determining the plurality of current path metrics comprises adding at least one first branch metric of the plurality of branch metrics to at least one of the plurality of prior path metrics to determine a first result, adding at least one second branch metric of the plurality of branch metrics to the at least one of the plurality of prior path metrics to determine a second result, and comparing the first result and the second result.

In some embodiments, adding the at least one first branch metric of the plurality of branch metrics to the at least one of the plurality of prior path metrics to determine the first result includes adding using modulo arithmetic, and adding the at least one second branch metric of the plurality of branch metrics to the at least one of the plurality of prior path metrics to determine the second result includes adding using modulo arithmetic.

In some embodiments, the plurality of branch metrics includes a respective set of branch metrics for each set of received values of the plurality of encoded signals. In some embodiments, each respective set of branch metrics represents a set of probabilities that the current set of received values of the plurality of encoded signals corresponds to a respective four hypothesis input signal values. In some embodiments, determining the plurality of branch metrics includes determining the plurality of branch metrics by processing a first and second received values of the current set of received values of the soft decision encoded signals separately from a third and fourth received values of the current set of received values of the soft decision encoded signals, and combining a first result of processing the first and second received values with a second result of processing the third and fourth received values.

In some embodiments, the first result includes four intermediate branch metrics, the second result includes four intermediate branch metrics, and each respective set of branch metrics includes sixteen branch metrics. In some embodiments, each branch metric of the plurality of branch metrics includes a five bit value. In some embodiments, the multi-stage Viterbi decoding comprises storing the plurality of pairs of current trace bits and sets of previously determined trace bits corresponding to prior sets of values of the plurality of encoded input signals, and determining the probable decoded signal based, at least in part, on the stored current and previously determined trace bits.

In some embodiments, determining the probable decoded signal comprises determining a sequence of hypothesis states based, at least in part, on the stored current and previously determined trace bits, and determining a set of values of the probable decoded signal based on the sequence of hypothesis states. In some embodiments, determining a sequence of hypothesis states comprises determining the sequence of hypothesis states by selecting a most likely hypothesis state corresponding to each respective set of received values of the plurality of encoded input signals in an order from the latest state to the earliest state.

In some embodiments, determining a set of values of the probable decoded signal comprises determining input values of a convolution algorithm that correspond to the sequence of hypothesis states. In some embodiments, each of the plurality of encoded input signals include a portion of a convolution coded signal and the probable decoded signal includes a decoding of the convolution coded signal. In some embodiments, receiving the plurality of encoded input signals comprises receiving the plurality of encoded input signals from a wireless transmitter. In some embodiments, the convolution coded signal includes a signal encoded with a convolution coding constraint of seven. In some embodiments, the multi-stage Viterbi decoding includes a two-stage radix-4 decoding. In some embodiments, the plurality of encoded input signals includes four soft decision encoded input signals.

### BRIEF DESCRIPTION OF THE DRAWINGS

The accompanying drawings are not intended to be drawn to scale. In the drawings, each identical or nearly identical component that is shown in various figures is represented by a like numeral. For purposes of clarity, not every component may be labeled in every drawing. In the drawings:

FIG. 1 shows a block diagram of two stations in a wireless communication network in accordance with some embodiments of the instant disclosure;

FIG. 2 illustrates a block diagram of a two-state radix-4 Viterbi decoder in accordance with some embodiments of the instant disclosure;

FIGS. 3A and 3B illustrate single state radix-2 and two state radix-4 trellis diagrams;

FIG. 4 illustrates a block diagram of one example add-compare-select unit in accordance with some embodiments of the instant disclosure;

FIG. 5 illustrates a cycling of operations among four memory banks in accordance with some embodiments of the instant disclosure; and

FIG. 6 illustrates a process of decoding a plurality of signals in accordance with some embodiments of the instant disclosure.

### DETAILED DESCRIPTION

Embodiments of the instant disclosure are not limited in their application to the details of construction and the arrangement of components and acts set forth in the following description or illustrated in the drawings. The instant disclosure is capable of other embodiments and of being practiced or of being carried out in various ways. Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

The word “exemplary” and variations thereof are used herein to mean “serving as an example, instance, or illustration.” Any embodiment or design described herein as “exemplary” is not necessarily to be construed as preferred or advantageous over other embodiments or designs.

Viterbi decoding techniques described herein may be used for various communication networks such as wireless wide area networks (WWANs), wireless metropolitan area networks (WMANs), wireless local area networks (WLANs), such as one implementing IEEE 802.11a, 802.11g and/or 802.11n, and so on. The terms “network” and “system” may be used interchangeably. The techniques may also be used with various multiple access schemes such as Frequency Division Multiple Access (FDMA), Code Division Multiple Access (CDMA), Time Division Multiple Access (TDMA), Spatial Division Multiple Access (SDMA), Orthogonal FDMA (OFDMA), Single-Carrier FDMA (SC-FDMA), Orthogonal Frequency Division Multiplexing (OFDM), and so on. An OFDMA network utilizes Orthogonal Frequency Division Multiplexing (OFDM). An SC-FDMA network utilizes Single-Carrier Frequency Division Multiplexing (SC-FDM). OFDM and SC-FDM partition the system bandwidth into multiple (K) orthogonal subcarriers, which may be referred to as tones, and/or bins. Each subcarrier may be modulated with data. In general, modulation symbols may be sent in the frequency domain with OFDM and in the time domain with SC-FDM.

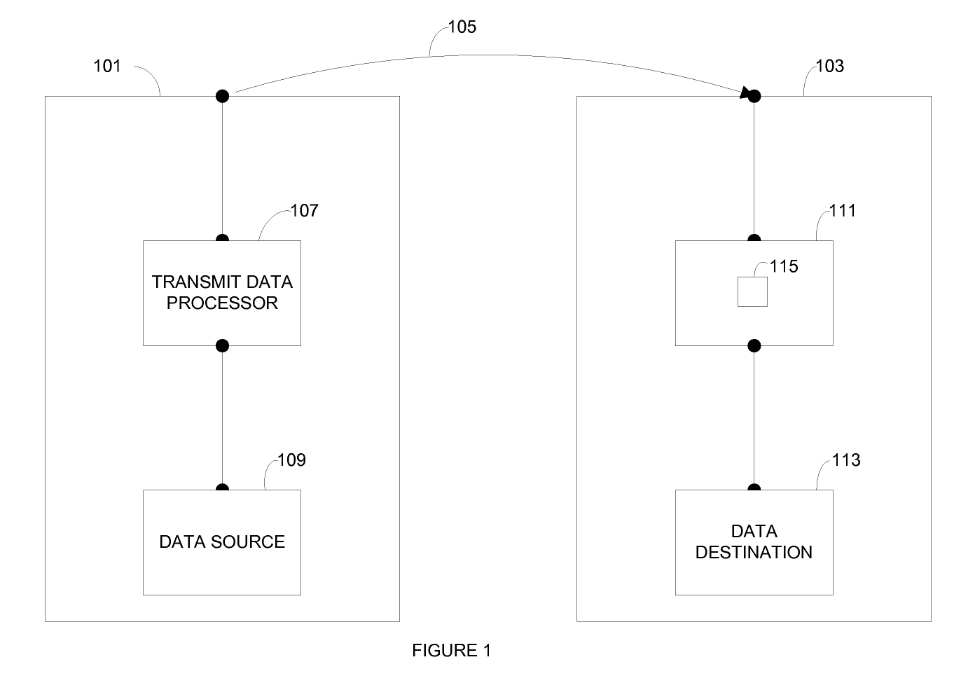

FIG. 1 shows a block diagram of an embodiment of two stations 101 and 103 in a wireless communication network 105. In FIG. 1, station 101 is acting as a transmitter of data and station 103 is acting as a receiver of data. It should be understood that in some embodiments, a single station may act as both a transmitter and a receiver of data.

Stations 101 and 103 may each be part of and/or may contain some or all of the functionality of, an access point, a base station, a node, a terminal, a mobile station, user equipment, a subscriber unit, and/or some other device or other network entity.

Station 101 in the illustrated embodiment of FIG. 1 may be equipped with multiple antennas. Station 103 in the illustrated embodiment of FIG. 1 may also be equipped with multiple antennas. A communication network in which a receiver station and a transmitter station each have multiple inputs/outputs (e.g., antennas) is referred to as a multiple-input multiple-output (MIMO) network. The IEEE 802.11n developing standard describes communication protocols that may be used in some implementations of a MIMO network. Each transmit antenna and each receive antenna may be a physical antenna or an antenna array. It should be understood that other embodiments of station 101 and/or station 103 may include a single antenna rather than multiple antennas.

At transmitter station 101, a transmit data processor 107 may receive data from a data source 109, and process the data to output a coded data signal for transmission through communication network 105. The data may include a data symbol and/or a pilot symbol. The data symbols and pilot symbols may be modulation symbols from a modulation scheme such as PSK or QAM. In some implementations, transmit data processor 107 may demultiplex the coded data signal for transmission in multiple streams through multiple output antennas.

In some embodiments, transmit data processor 107 may code data from data source 109 using a well-known convolution encoding technique. Convolution encoding paired with Viterbi decoding, which is discussed below, may reduce error rates associated with the transmission of data over a wireless network. In brief, convolution encoding may convert an m input data bits into n coded output bits based, at least in part on a number of previous input bits. Each input bit is coded based on a number of previous input bits. The previous input bits and the input bit being coded are applied as input to a collection of modulo adders in accordance with a set of generator polynomials. The output of each modulo adder may then be used to generate one of the output coded bits. The collection of output coded bits may make up the coded data signal. Embodiments of the instant disclosure may be used with any convolution coding having any values for m and n and using any number of prior bits to perform convolution coding. In some implementations, m may equal one and n may equal two. In other implementations, m may equal two and n may equal four. In some implementations, the number of prior bits may equal six.

In some embodiments, the coded data signal may be received by receiver station 103 (e.g., by multiple receive antennas). At receiver station 103, a receive data processor 111 may receive the coded data signal from the receive antennas, and process the data to decode the coded signal and then output the decoded signal to a data destination 113.

In some embodiments of the instant disclosure, receive data processor 111 may include a multi-state Viterbi decoder (e.g., radix-4 Viterbi decoder 115). A multi-state Viterbi decoder may process multiple state transitions of a single-stage trellis state diagram in parallel. A radix-4 two state Viterbi decoder 115 is described below as one example of a multi-state Viterbi decoder, but embodiments of the instant disclosure are not so limited.

Radix-4 Viterbi decoder 115 may be used to determine a likely sequence of data input to transmit data processor 107 based on a received coded representation of that data. Radix-4 Viterbi decoder 115 may provide adequate decoding speeds for use in modern technology such as the IEEE 802.1n developing standard. Radix-4 decoder 115 may be configured to trace the convolution coding states according to a radix-4 trellis, as described above.

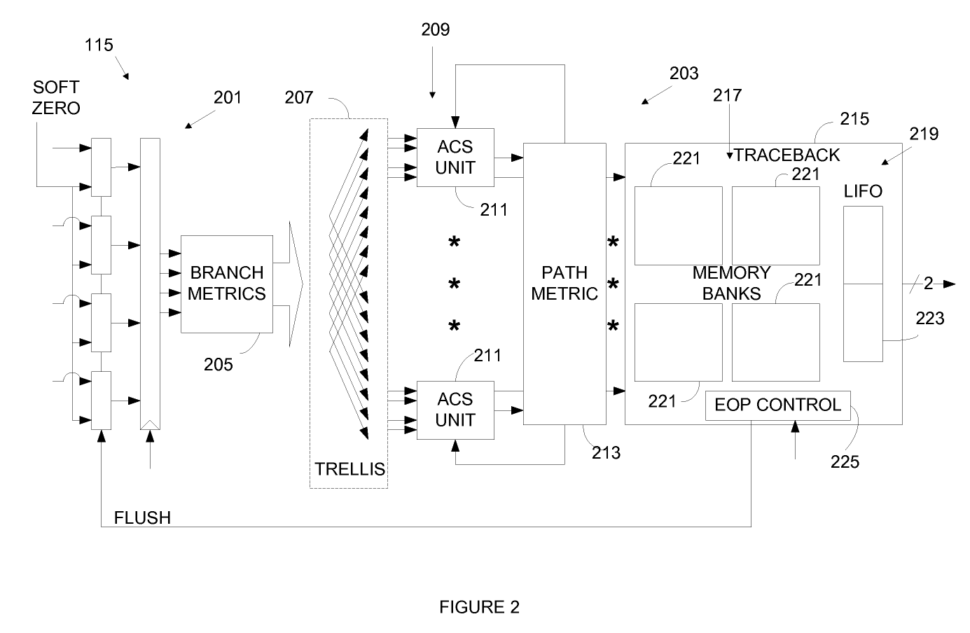

FIG. 2 illustrates a block diagram of radix-4 Viterbi decoder 115 in more detail. As illustrated, radix-4 Viterbi decoder 115 includes an input element 201 and a Viterbi decoding element 203.

In some embodiments, input element 201 may accept input of four soft decision encoded input signals. A soft decision encoded input signal may include a confidence in a hypothesis bit value. In some embodiments, for example, a value of each of the soft-decision encoded input signals may include a multi-bit magnitude and a sign. In some implementations, the sign may represent a hypothesis bit value (e.g., 1 or 0) and the magnitude may represent a confidence that the bit value is correct. A higher magnitude, for example may indicate more confidence in the bit value. In some implementations, each magnitude may include three bits. It should be recognized that the instant disclosure, however, is not limited to soft decision input signals and that in some implementations, hard decision input signals may be used.

It should be understood that four input signals are used in the described example because of the common use of ½ convolution coding in which two encoded bits are generated for each input bit into a convolution coder. Because a radix-4 Viterbi decoder may decode two trellis stages substantially simultaneously, corresponding to two input bits, four coded bits would be used (e.g., twice the number of coded bits generated for one input bit). In other embodiments, other convolution coding schemes may be used and so another number of input signals and corresponding radix order may also be used.

In some embodiments, radix-4 Viterbi decoder element 203 may be configured to process the four soft decision input signals to determine a probable decoded signal. In some embodiments, to achieve high data throughput, radix-4 decoder element 203 may generate two trace bits (e.g., bits corresponding to state transitions in a two stage trellis) substantially simultaneously rather than separately as is done in traditional radix-2 Viterbi decoders.

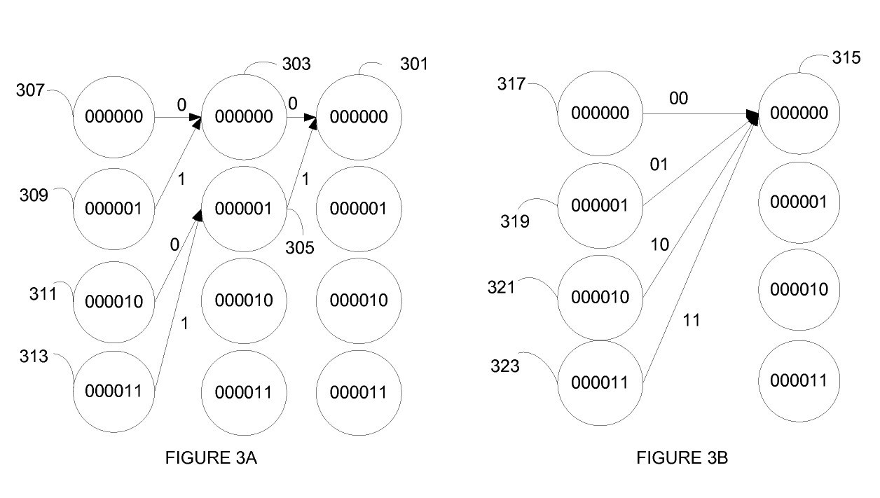

To help explain this process, FIGS. 3A and 3B illustrate trellis diagrams that may provide useful illustrations. FIG. 3A illustrates a portion of a traditional single stage radix-2 trellis diagram. FIG. 3A illustrates three time periods in a convolution coder or Viterbi decoder, and four out of sixty-four possible states for each time period. In the illustrated example, if the final state is state 301 (e.g., the state corresponding to bits 000000), then, in a single stage radix-2 trellis, only states 303 and 305 would be possible prior states (e.g., states corresponding to bits 000001 and 000000), because in radix-2 trellises, as is well known in the art, only a single bit may change in each state transition. This same process may be applied to perform an additional step backwards in time through the trellis to any of the four states 307, 309, 311, or 313 (e.g., states corresponding to bits 000000, 000001, 000010, and 000011) that may be prior states to states 303 and 305. The example trellis diagram corresponds to a convolution coding having a k constraint of seven, as is well known in the art, but it should be recognized that any convolution coding constraints may be used in various embodiments and that the number of states in a trellis may vary based on the convolution coding constraint chosen.

In one aspect of the instant disclosure, it is recognized that the single stage radix-2 trellis may be compressed to a two stage radix-4 trellis in which two single stage radix-2 transitions occur in a single two stage radix-4 transition. FIG. 3B illustrates a two stage radix-4 trellis in which each transition from one state to another represents two stages of the single stage radix-2 trellis of FIG. 3A. It should be appreciated, that in the two stage radix-4 trellis, each state may have four possible prior states rather than two because two new bits are added to the state rather than one as in the single stage radix-2 trellis. As is illustrated, state 315 of the two stage radix-4 trellis, which corresponds to state 301 of the single stage radix-2 trellis and has bits 000000, has four possible prior states 317, 319, 321, and 323, which correspond to states 307, 309, 311, and 313 of the single stage radix-2 trellis and have bits 000000, 000001, 000010, and 000011.

In some embodiments, the general structure of radix-4 Viterbi decoder element 203 may follow a similar structural pattern of a traditional radix-2 Viterbi decoder. For example, radix-4 Viterbi decoder element 203 may include a branch metric element 205, an add-compare element 209, a path metric element 213, and a traceback element 215 as illustrated in FIG. 2 and described in more detail below.

As indicated in FIG. 2, radix-4 Viterbi decoder element 203 may include an input and flush element 201 configured to accept respective input signal values for each of the four soft decision input signals and to provide flush functionality at the end of a packet, as is described in more detail below.

As indicated in FIG. 2, radix-4 Viterbi decoder element 203 may include a branch metric element 205. Branch metric element 205 may be configured to generate a plurality of branch metrics based on a set of values of the four soft decision input signals. In some embodiments, each branch metric represents a probability that the current set of values of the four soft decision input signals corresponds to a respective four hypothesis input signal values. In some embodiments, branch metric element 205 may generate a set of branch metrics for each set of values of the four soft decision input signals and for each of the possible hypothesis input signal values (e.g., any four bit combination of 1's and 0's). In some embodiments, branch metric element 205 may generate sixteen (i.e., 2^{z} where z is the radix order) branch metrics for each set of values of the four soft decision input signals.

In some embodiments, branch metric element 205 may be configured to process the four soft-decision input signals in pairs rather than as a group of four to generate branch metrics. In some implementations, each of the two pairs may be used by branch metric element 205 to generate four respective intermediate branch metrics. In some implementations in which sign of a value indicates a hypothesis bit value ( i.e., 0 or 1), as described above, each of the four intermediate branch metrics may be the sum of the differences in magnitudes of each signal value that differs in sign from a hypothesis signal value. In some implementations, a complete set of hypothesis bit values for each set of intermediate values is given by the matrix:

$$[ \begin{matrix}1 & - 1 & 1 & - 1 \\ 1 & 1 & - 1 & - 1\end{matrix} ]$$

where each column represents a hypothesis value for a respective pair of input signal values, a 1 represents a hypothesis 1 value and a −1 represents a hypothesis 0 value. An intermediate branch metric (IBM) for a respective pair of input values b1 and b2 may be determined as IBM=b1*h1+b2*h2, where h1 and h2, are the hypothesis values, e.g., +/−1 from a respective column of the matrix above. In some implementations, if b1 and h1 have the same sign, the value of b1*h1 may be set to zero, and likewise if b2 and h2 have the same sign, the value of b2*h2 may be set to zero.

In some embodiments, branch metric calculation may be further simplified. For example, in some embodiments, a bias of |b1|+|b2| may be added to each intermediate branch metric leading to: BM=b1*h1+b2*h2+|b1|+|b2|. In such implementations, b1*h1 and |b1| may be set to zero if b1 and h1 have the same sign, and likewise b2*h2 and |b| may be set to zero if b2 and h2 have the same sign. In such implementations, intermediate branch metrics then take on possible values 0, 2*|b1|, 2*|b2|, 2*(|b1|+|b2|), and all intermediate branch metrics are even. In such implementations, intermediate branch metrics may be divided by 2 yielding possible values of 0, |b1|, |b2|, |b1|+|b2|, eliminating the need to perform a multiplication to determine the intermediate branch metrics and reducing the number of bits needed to store the intermediate branch metrics to four for three bit input values b1, b2. The pair-wise computation of intermediate branch metrics may yield eight total intermediate branch metrics, four for each pair of soft decision convolution coded input signals. The intermediate branch metrics may take on binary values in the range of zero to fourteen.

In some embodiments, intermediate branch metrics may be summed to generate branch metrics for each hypothesis combination of the radix-4 input signals. The metrics may be combined, for example, to produce a final sixteen radix-4 branch metrics so that each hypothesis is associated with a branch metric. The sixteen hypotheses are given by the matrix:

$$[ \begin{matrix}1 & & - 1 & & 1 & & - 1 & & 1 & & - 1 & & 1 & & - 1 & & 1 & & - 1 & & 1 & & - 1 & & 1 & & - 1 & & 1 & & - 1 \\ 1 & & 1 & & - 1 & & - 1 & & 1 & & 1 & & - 1 & & - 1 & & 1 & & 1 & & - 1 & & - 1 & & 1 & & 1 & & - 1 & & - 1 \\ 1 & & 1 & & 1 & & 1 & & - 1 & & - 1 & & - 1 & & - 1 & & 1 & & 1 & & 1 & & 1 & & - 1 & & - 1 & & - 1 & & - 1 \\ 1 & & 1 & & 1 & & 1 & & 1 & & 1 & & 1 & & 1 & & - 1 & & - 1 & & - 1 & & - 1 & & - 1 & & - 1 & & - 1 & & - 1\end{matrix} ]$$

In some implementations, the final branch metrics range from zero to twenty-eight in binary and may use five binary bits for representation.

It should be recognized that a soft decision encoded input signal may include any number of bits. The present example is given with respect to a three bit magnitude signal having a sign bit, but the embodiments are not so limited. Likewise, intermediate branch metrics and branch metrics may be represented using any number of bits and in any fashion, The example above is given as one possible example in which intermediate branch metrics and branch metrics may be computed and is not meant to be limiting.

In some embodiments, radix-4 Viterbi decoder element 203 may include a trellis interconnect element 207 configured to provide the branch metrics from branch metric element 205 to add-compare element 209. In some implementations, trellis interconnect element 207 may include a communication network, such as a system bus.

In some embodiments, as described above, each state in a two stage Radix-4 trellis (e.g., the trellis shown in FIG. 3B) may have possible state transitions from four possible previous states. Trellis interconnect element 207 may be configured to follow the possible state transitions into a respective state of the radix-4 Viterbi algorithm by providing the add-compare element 209 with branch metrics arranged according to possible state transitions into a respective current state. The trellis arrangement may be specific to a particular encoding scheme because the input signal values that correspond to each state transition may depend on the convolution generator polynomials used by the convolution coder, as is well known in the art.

In some embodiments, as mentioned above, radix-4 Viterbi decoder element 203 may include an add-compare element 209. Add-compare element 209 may include sixty-four parallel add-compare-select units, some of which are identified at 211. The number of add-compare select units 211 may correspond to the number of possible current states in a trellis (e.g., sixty-four in the trellis example of FIG. 3B). It should be understood that various embodiments are not limited to any particular number of add-compare-select units 211.

Each one of the add-compare-select units 211 may be thought of as determining information about a current state of a two stage radix-4 trellis diagram. For example, one add-compare-select unit may be configured to determine information regarding state 315 of the trellis diagram of FIG. 3B. The information may include determining a probability of being in state 315 and a most likely path to reach state 315. Such information may be determined by summing each of the branch metrics corresponding to the four possible transitions from the four possible prior states with a respective path metric corresponding to a probability of being in a respective one of the possible prior states (e.g., states 317, 319, 321, and 323).

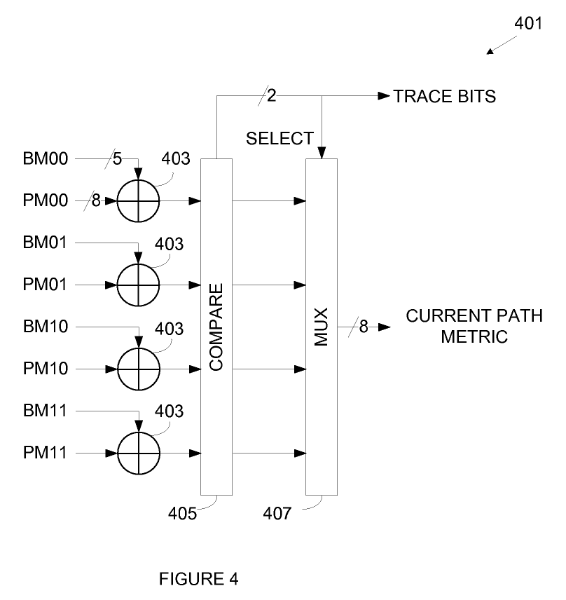

FIG. 4 illustrates a block diagram of one example add-compare-select unit 401 that may be used as one of the add-compare-select units 211 of FIG. 2. In some implementations, add-compare-select unit 405 may be implemented using ninety nanometer lithography technology. Add-compare-select unit 401 may process four branch metrics received from trellis interconnect element 209. As described above, the four branch metrics received by add-compare-select 401 may correspond to probabilities that a set of four soft decision input signal values correspond to four possible state transitions into a respective current state of a radix-4 trellis (e.g., into state 315 from each of states 317, 319, 321, and 323). Together, the sixty-four add-compare-select units of add-compare select element 209 may accept branch metrics that correspond to all the possible transitions to each of the possible sixty-four current states of a sixty-four state two stage radix-4 trellis.

In some embodiments, add-compare-select unit 401 may also receive four prior path metrics. In some implementations, the four prior path metrics may be received from prior path metric element 215. Each of the four prior path metrics may correspond to a probability of being in one of four prior states in a two stage radix-4 trellis. The four prior states may include the four possible prior states of a current state represented by a particular add-compare-select element. For example, if a particular add-compare-select element represents current state 315, the four path metrics may represent probabilities associated with each of possible prior states 317, 319, 321, and 323.

In some embodiments, add-compare-select unit 401 may be configured to determine which of the four combinations of prior state and state transition is most likely. Such a determination may be made by adding each of the four pairs of branch and path metrics and comparing the four sums. In some embodiments, the lowest of the four sums may be chosen as the most likely combination. In some implementations, a well-known modulo-arithmetic approach may be used to add and compare the respective sums to avoid a maximum metric search and normalization. In such an implementation, add-compare-select unit 401 may include a plurality of modulo adders, each indicated at 403 and configured to add a respective branch metric and path metric pair.

In some implementations, add-compare-select unit 401 may include a compare element 405 that may compare the sums output by modulo adders 403. In some implementations, compare element 405 may use a comparison tree implemented with subtractors, as is known in the art. In some embodiments, compare element 405 may determine and output two trace bits corresponding to a determined most likely transition into a current state (e.g., state 315) represented by a respective add-compare-select unit. The two output trace bits may correspond to the two least significant bits of a previous state. For example, an add-compare-select unit determining information regarding state 315 may compare possible transitions from states 317, 319, 321, and 323 to determine a most probable prior state. In one example, if state 323 is the most probable prior state, then the trace bits 11 correspond to the two least significant bits of state 323 may be determined and output as the trace bits.

In some implementations, an add-compare-select unit may include a multiplexer 407 into which each of the four sums of respective branch and path metric pairs are input. In such implementations, the output trace bits of compare element 405 may be used to select one of the sums as a new path metric to be output to path metric element 213 (e.g., by multiplexer 407). The new path metric represents a probability of a most-likely path to a respective current hypothesis state, e.g., the sum of the chosen combination of prior path metric and branch metric for a current path represented by the respective add-compare-select unit (e.g. state 315). The new path metric may be stored in a path metric element 213, described below, for use in a next cycle through the Viterbi decoder (e.g., for a next set of values of the four soft decision input signals).

In some embodiments, radix-4 Viterbi decoder element 203, as illustrated in FIG. 2, may include a path metric element 213. Path metric element 213 may include a plurality of memory units configured to store current path metrics that are generated by respective add-compare-select units. In some implementations, path metric element 213 may be configured to receive the current path metrics from the add-compare-select units and provide the same add-compare-select units with prior path metrics from an immediately previous computation (e.g., corresponding to a previously received set of values of the encoded input signals). On each processing cycle of Viterbi decoder element 203, path metric element 213 may replace prior determined path metrics with newly determined path metrics 213 from the add-compare-select units. In some implementations, the path metric element may include a plurality of registers in which path metrics are stored. In one implementation, the plurality of registers may include a plurality of eight bit registers.

In some embodiments, radix-4 Viterbi decoder element 203 may include a traceback element 215 configured to determine decoded signals based, at least in part, on recorded trace bits. Traceback element 215 may receive traceback bits output by the add-compare select units, store and process them to determine a decoded sequence of bits. In some embodiments, traceback element 215 may be divided into two sections, a survivor traceback section 217 and an output reordering section 219.

In some embodiments, input and flush element 201, branch metric element 205, trellis interconnect 207, add-compare element 209 and/or path metric element 213, may be configured to process a new set of trace bits each traceback interval (e.g., clock tick) and provide traceback element 215 with information regarding the newly determined trace bits.

In some embodiments, survivor-path traceback section 217 may include a plurality of memory banks, each indicated at 221. In one implementation, survivor-path traceback section 217 may use a well-known k-even pointer algorithm whereby read and write operations are performed in parallel on sub-divided memory banks to improve performance. In some implementations, for example, for a given k value and traceback length T, the required memory may be divided into 2*k memory banks. In some implementations, a k value of two may be used, leading to four memory banks. It should be understood that k may include any value in other implementations.

Furthermore, it should be understood that T may include any value. In the illustrated implementation, T may be one hundred twenty-eight bits, corresponding to one hundred twenty-eight trace bits. The value of T may indicate the number of trace bits that are stored for each decoding set, as is known in the art. Increasing T may increase latency of decoding as well as the confidence in the final decoding, as is known in the art. To accommodate a T of one hundred twenty-eight, four single-port 64×128 RAM banks may be used. In some implementations, two dual-port 128×128 may be used instead. In some implementations, increasing the word size by two may double the memory area whereas increasing the word depth may only increase the memory by ˜20%, so increasing word depth may improve memory size in a smaller area.

In some embodiments, survivor-path traceback section 217 may perform four parallel processes during every traceback interval (e.g., clock tick). In some implementations, each of the four parallel processes may include one of WRITE, TRACE, IDLE, and DECODE. In some implementations, the WRITE process may store the trace bits generated by the add-compare-select element as they arrive. In some implementations, the TRACE process may operate on a traceback length (T) block of data (e.g., trace bits) stored in a memory bank, beginning with the last entry and working back to the first entry to derive a starting point (e.g., a state) for the DECODE process. In some implementations, because the TRACE process works on later input data to allow decoding of previously received data, the past block of data is maintained in an IDLE process until the later input data is received.

In some implementations, once the TRACE process completes decoding a full set T of bits (e.g., one hundred twenty-eight) to determine, the resultant starting point may be used to begin the DECODE process, which follows a similar backwards trace and produces the decoded bits of the convolution encoded input signal in reverse order. The DECODE process may operate similar to a single stage radix-2 Viterbi decoder DECODE process, except that the state transitions in a two stage radix-4 DECODE process may correspond to two state transitions in a single stage radix-2 DECODE process. The DECODE process may determine a sequence of input bits to a convolution encoder that would result in the determined trace bits. After both, the TRACE and DECODE processes, 2*T bits may have been decoded, T during the TRACE process and T during the DECODE process. The first T during the TRACE process may be decoded so that the first bit decoded during the DECODE process has at least a confidence corresponding to a traceback length T, as is known in the art.

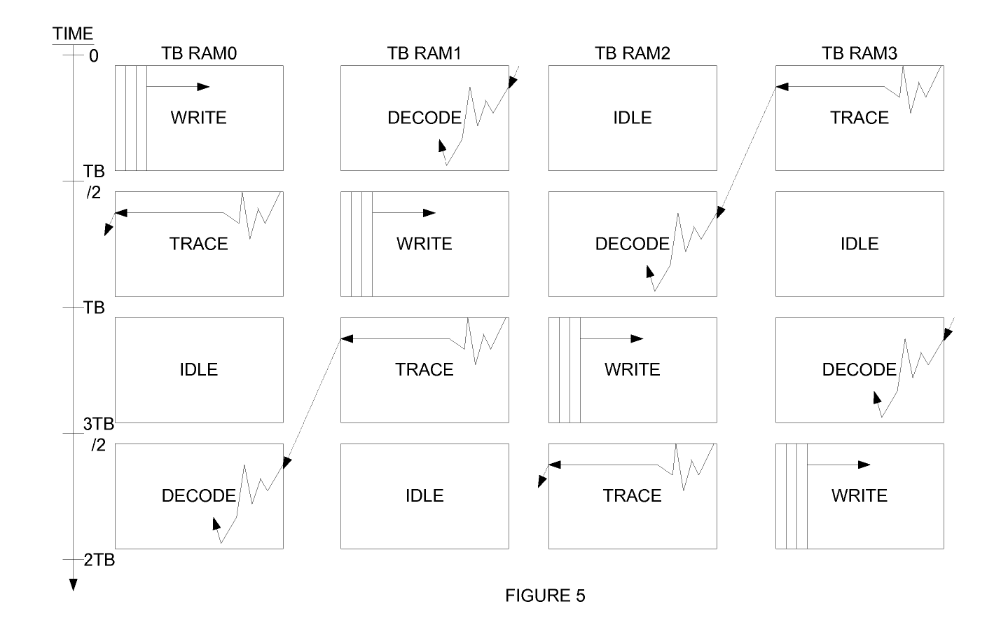

In some embodiments, these four processes may be distributed among each of the plurality of memory banks. In some implementations, processes being performed by each memory bank may cycle at each traceback boundary (e.g., each T clock ticks). FIG. 5 illustrates a cycling of operations among four memory banks according to some implementations.

FIG. 5 illustrates the functions being performed on each of four memory banks (TB RAM0, TB RAM1, TB RAM2, and TB RAM3) according to some embodiments of the instant disclosure. As illustrated, memory bank TB RAM0 may begin a series of clock cycles by performing a WRITE operation. During the clock cycles in which the WRITE operation is being performed, a sequence of trace bits may be written into the memory bank TB RAM0. At the next set of clock cycles, the trace bits written into the same memory bank may be used to perform a TRACE operation. The TRACE operation may determine a likely sequence of states that resulted in the written trace bits and output a beginning state to be used to decode the bits that are then stored in memory bank TB RAM3.

In some embodiments, in the next set of clock cycles, memory bank TB RAM0 may remain idle as the bits in memory bank TB RAM3 are decoded and the bits in TB RAM1 are used in a TRACE operation. The result of the TRACE operation on the bits in the memory bank TB RAM1 may then be used as a starting point to decode the bits in the memory bank TB RAM0 in the next set of clock cycles. At the fourth set of clock cycles, the bits in the memory bank TB RAM0 may be used to perform a DECODE operation to determine the decoded bit sequence using the output of the TRACE operation performed on the bits in the memory bank TB RAM1 as a starting point.

As mentioned above, in some embodiments, the DECODE process produces bits in reverse order. Traceback element 215 may include an output reordering section 219. Output reordering section 219 may include a Last-In-First-Out (LIFO) double-buffer 223 to restore the output bits to a forward order. In one implementation, each buffer may be 64 bits×2. In some implementations, while reverse-order data is being written in one buffer, a decoded signal in forward order may be read from the second buffer.

In some embodiments, radix-4 Viterbi decoder element 203 may include an end of packet control 225 that is shown in FIG. 2 as part of the traceback element 215. End of packet control 225 may be configured to determine when a packet ends or receive an indication of a packet end so that the Viterbi decoder 115 may be flushed of data in preparation for decoding a next packet. Such flushing may be performed to match the flushing of a convolution encoder. In some implementations, since IEEE 802.11 standards include packet length identifiers in each packet, a last bit of a packet may be determined from a length identified in the packet during the receipt of the packet. This length may be compared to the length of a packet as it is being received so that an end of a packet may be determined. In some implementations, since the end portion of a packet is not limited to traceback intervals, the last decode block for a packet may not have the benefit of a full traceback and may therefore experience both less latency and less certainty.

In some implementations, end of packet control 225 may flush Viterbi decoder 115 to maintain an initial zeroed state by entering soft-decision zero inputs into input and flush element 201. This may be accomplished, for example, by selecting the output of a multiplexer having one input set to the soft decision zero and the other input set to the encoded input signal.

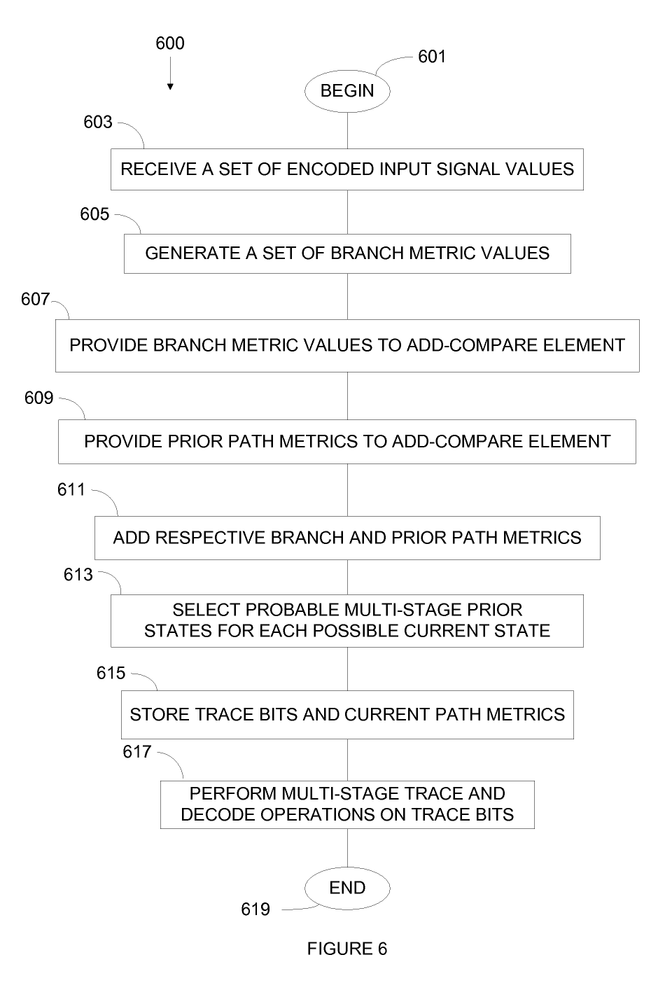

Having described an example set of hardware and respective functionality of an example radix-4 Viterbi decoder 115, an example process of decoding four encoded input signals may be described. Process 600 illustrated in FIG. 6 and that begins at block 601 may be used for such decoding. It should be understood that while example process 600 describes decoding in accordance with a two stage radix-4 trellis, the present disclosure is not limited to such decoding. Rather, various embodiments of the instant disclosure may decode according to any multi-stage trellis.

As indicated at block 603, process 600 may include an act of receiving four encoded input signal values. These signal values may be received for example, by an input element of a radix-4 Viterbi decoder. As described about, the number of encoded input signals may correspond to the convolution encoding scheme, but is described herein as four as an example only.

As indicated at block 605, the four encoded input signal values may be used to generate a set of current branch metric values. The branch metric values may correspond to the probabilities that the set of four encoded input values is actually any one of a possible sixteen input options. As described above, the branch metrics may be generated by computing intermediate branch metrics for each two of the input signal values and then combining the results to generate the sixteen total branch metrics, one for each possible set of values corresponding to possible received coded signal values.

As indicated at block 607, process 600 may include an act of providing the branch metrics to an add-compare element. Providing the branch metrics may include transmitting a representation of each of the branch metrics on a communication network (e.g., a system bus). Providing the branch metrics may include providing a subset of the branch metrics to each of a plurality of add-compare-select units of the add-compare element. The branch metrics may be provided so that each respective add-compare-select unit receives four branch metrics that correspond to four possible state transitions that may result in a transition into a current state represented by the respective add-compare-select unit.

As indicated at block 609, process 600 may include providing path metrics to an add-compare-select element. The path metrics may be provided, as described above, from a path metric element. The path metrics may each represent a probability associated with one of the possible sixty-four prior states in a sixty-four state two stage radix-4 trellis. The path metrics may be provided to respective add-compare select units so that each add-compare-select unit is provided with four path metrics that correspond to the four branch metrics that were provided in block 607. It should be recognized that acts represented by blocks 607 and 609 may be performed substantially simultaneously for a set of received input signal values rather than in sequence as shown in FIG. 6.

As indicated in block 611, process 600 may include adding branch metrics and path metrics. In some implementations, each add-compare-select unit may add a branch metric and path metric pairs as described above.

As indicated in block 613, process 600 may include selecting prior states for each possible current state. Selecting the prior states may include comparing the sums of added branch and path metric pairs within each add-compare-select unit and choosing the combination that corresponds to the lowest sum. Selecting prior states may include generating trace bits corresponding to the state transition from the selected prior state to the current state, and generating current path metrics that correspond to the probability of being in each current state (e.g., the sums).

As indicated in block 615, process 600 may include storing trace bits and next path metrics. The next path metrics may be stored in a path metric element, as described above. The next path metric may include the lowest sum computed by each add-compare-select unit described at block 611 and 613. These next path metrics may in turn be used to compute a next set of path metrics by being input into the add-compare-select units again when the next set of branch metrics are input into the add-compare-select units (e.g., at block 609).

As indicated in block 617, process 600 may include performing a TRACE and DECODE operation to determine the probable input bits to a convolution encoder (e.g., transmit data processor 107). The combined TRACE and DECODE operations may determine 2*T bits to decode T bits, where T is the traceback length, as is known in the art. The TRACE and DECODE operations, for example, may reference a set of last determined trace bits and last determined path metrics. The current state corresponding to the lowest path metric may be chosen as the most probable current state. The states may be traced back T states during the TRACE operation. Then, another T states may be traced back during the DECODE operation. As states are traced back during the DECODE operation, trace bits corresponding to state transitions may be output in reverse order to an output reordering section.

The techniques described herein may be implemented in MIMO wireless communications systems, as well as in any communication system, wireless or otherwise, in which one or more pilot tones are employed. The techniques described herein may be implemented in a variety of ways, including hardware implementation, software implementation, or a combination thereof. For a hardware implementation, the processing units used to process data for transmission at a transmitting station and/or for receipt at a receiving station may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, electronic devices, other electronic units designed to perform the functions described herein, or a combination thereof. In embodiments in which the transmit and receive stations include multiple processors, the processors at each station may share hardware units.

For a software implementation, the data transmission and reception techniques may be implemented with software modules (e.g., procedures, functions, and so on) that perform the functions described herein. The software codes may be stored in a memory unit (e.g., memory unit 242 or 282 in FIG. 2) and executed by a processor (e.g., controller 240 or 280). The memory unit may be implemented within the processor or external to the processor.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed embodiments is provided to enable any person skilled in the art to make or use the disclosure. Various modifications to these embodiments will be readily apparent to those skilled in the art, and the generic principles defined herein may be applied to other embodiments without departing from the spirit or scope of the disclosure. Thus, the disclosure is not intended to be limited to the embodiments shown herein but is to be accorded the widest scope consistent with the principles and novel features disclosed herein.

What is claimed is:

1. A decoder apparatus comprising:
an input element configured to receive a plurality of encoded input signals; and
a multi-stage Viterbi decoder element configured to process the plurality of encoded input signals to determine a probable decoded signal.

2. The apparatus of claim 1, wherein the multi-stage Viterbi decoder element includes a radix-4 Viterbi decoder element.

3. The apparatus of claim 1, wherein the multi-stage Viterbi decoder element comprises:
a branch metric element configured to determine a plurality of branch metrics; and
an add-compare element configured to determine a plurality of current path metrics, and configured to output a plurality of pairs of current trace bits, each pair of trace bit corresponding to a respective one of the plurality of current path metrics.

4. The apparatus of claim 3, wherein the add-compare element is configured to determine the plurality of current path metrics based on the plurality of branch metrics and a plurality of prior path metrics.

5. The apparatus of claim 4, wherein each current path metric represents a probability of a most-likely path to a respective current hypothesis state, the probability corresponding to a respective branch metric of the plurality of branch metrics and a respective prior path metric of the plurality of prior path metrics.

6. The apparatus of claim 4, wherein each prior path metric represents a probability of a most likely path to a respective previous hypothesis state corresponding to a prior set of received values of the plurality of encoded input signals.

7. The apparatus of claim 3, wherein the plurality of branch metrics includes a respective set of branch metrics for each set of received values of the plurality of encoded signals.

8. The apparatus of claim 7, wherein each respective set of branch metrics represents a set of probabilities that the current set of received values of the four soft decision encoded signals corresponds to a respective four hypothesis input signal values.

9. The apparatus of claim 3, wherein the branch metric element is configured to determine each respective set of branch metrics by processing a first and second received values of the current set of received values of the plurality of encoded signals separately from a third and fourth received values of the current set of received values of the plurality of encoded signals and then combining a first result of processing the first and second received values with a second result of processing the third and fourth received values.

10. The apparatus of claim 9, wherein the first result includes four intermediate branch metrics, the second result includes four intermediate branch metrics, and each respective set of branch metrics includes sixteen branch metrics.

11. The apparatus of claim 9, wherein each branch metric of the plurality of branch metrics includes a five bit value.

12. The apparatus of claim 3, wherein the multi-stage Viterbi decoder element comprises:
a trellis element configured to provide the add-compare element with the plurality of branch metrics; and
a path metric element configured to store the plurality of current path metrics.

13. The apparatus of claim 12, wherein the add-compare element is configured to determine the plurality of current path metrics based on the plurality of branch metrics and a plurality of prior path metrics, and wherein the path metric element is configured to provide the add-compare element with the plurality of prior path metrics.

14. The apparatus of claim 3, wherein the multi-stage Viterbi decoder element comprises a traceback element configured to store the plurality of pairs of current trace bits and pairs of previously determined trace bits corresponding to prior sets of received values of the plurality of input signals, and configured to determine the probable decoded signal based, at least in part, on the stored current and previously determined trace bits.

15. The apparatus of claim 14, wherein the traceback element is configured to determine a sequence of hypothesis states based, at least in part, on the stored current and previously determined hypothesis state values, and to determine a set of values of the probable decoded signal based on the sequence of hypothesis states.

16. The apparatus of claim 20, wherein the traceback element is configured to determine the sequence of hypothesis states by selecting a most likely hypothesis state corresponding to each respective set of received values of the plurality of encoded signals in an order from the latest state to the earliest state.

17. The apparatus of claim 16, wherein the traceback element is configured to determine the set of values of the probable decoded signal by determining input values of a convolution algorithm that correspond to the sequence of hypothesis states.

18. The apparatus of claim 17, wherein the traceback element comprises four memory elements, and the traceback element is configured to use each memory element of the four memory elements to perform at least one of a trace operation, an idle operation, a write operation, and a decode operation.

19. The apparatus of claim 1, wherein each of encoded input signals include a portion of a convolution coded signal and the probable decoded signal includes a decoding of the convolution coded signal.

20. The apparatus of claim 19, wherein the plurality of convolution coded signals includes a signal encoded with a convolution coding constraint of seven.

21. A decoder comprising:
an input element configured to receive a plurality of encoded input signals; and
a means for determining a probable decoded signal by performing a multi-stage Viterbi decoding process on the plurality of encoded input signals.

22. The apparatus of claim 21, wherein the means for determining a probable decoded signal comprises:
a means for determining a plurality of branch metrics, each branch metric representing a probability that current received values of the four soft decision encoded input signals correspond to a respective four hypothesis input signal values;
a means for determining a plurality of current path metrics based on the plurality of branch metrics and a plurality of prior path metrics, each current path metric representing a probability of a most likely path to a respective hypothesis current state corresponding to a set of current received values of the four soft decision encoded signals; and
a means for determining a plurality of current trace bits, each corresponding to a respective one of the plurality of current path metrics and the current set of received values of the four soft decision encoded signals.

23. The apparatus of claim 22, wherein the means for determining a probable decoded signal comprises:
a means for providing the means for determining a plurality of current path metrics with the plurality of branch metrics;
a means for storing the plurality of current path metrics; and
a means for providing the means for determining a plurality of current path metrics with the plurality of prior path metrics, each prior path metric representing a probability of a most likely path to a respective previous hypothesis state corresponding to a prior set of received values of the plurality of encoded input signals.

24. The apparatus of claim 22, wherein the means for determining a probable decoded signal comprises:
a means for storing the current hypothesis state value for each of the plurality of current path metrics and a plurality of pairs of previously determined trace bits corresponding to previously received values of the encoded input signals; and
a means for determining the probable decoded signal based, at least in part, on the stored current and previously determined trace bits.

25. The apparatus of claim 24, wherein the means for determining the probable decoded signal comprises:
a means for determining a sequence of hypothesis states based, at least in part, on the stored hypothesis state values, and
a means for determining a set of values of the probable decoded signal based on the sequence of hypothesis states.

26. The apparatus of claim 25, wherein the means for determining the probable decoded signal comprises a means for determining the sequence of hypothesis states by selecting a most likely hypothesis state corresponding to each respective set of received values of the plurality of encoded signals in an order from the latest state to the earliest state.

27. The apparatus of claim 26, wherein the multi-stage Viterbi decoding process includes a two-stage Radix-4 Viterbi decoding process.

28. A method of decoding an encoded input, the method comprising:
receiving a plurality of encoded input signals; and
performing a multi-stage Viterbi decoding on the plurality of soft decision encoded input signals to determine a probable decoded signal.

29. The method of claim 28, wherein Viterbi decoding comprises:
determining a plurality of branch metrics;
determining a plurality of current path metrics; and
determining a plurality of pairs of current trace bits, each corresponding to a respective one of the plurality of current path metrics.

30. The method of claim 29, wherein determining the plurality of current path metrics comprises determining the plurality of current path metrics based on the plurality of branch metrics and a plurality of prior path metrics.

31. The method of claim 30, wherein each current path metric represents a probability of a most-likely path to a respective current hypothesis state, the probability corresponding to a respective branch metric of the plurality of branch metrics and a respective prior path metric of the plurality of prior path metrics.

31. The method of claim 30, wherein each prior path metric represents a probability of a most likely path to a respective previous hypothesis state corresponding to a prior set of received values of the plurality of encoded input signals.

32. The method of claim 30, wherein determining the plurality of current path metrics comprises:
adding at least one first branch metric of the plurality of branch metrics to at least one of the plurality of prior path metrics to determine a first result;
adding at least one second branch metric of the plurality of branch metrics to the at least one of the plurality of prior path metrics to determine a second result; and comparing the first result and the second result.

33. The method of claim 32, wherein adding the at least one first branch metric of the plurality of branch metrics to the at least one of the plurality of prior path metrics to determine the first result includes adding using modulo arithmetic; and wherein adding the at least one second branch metric of the plurality of branch metrics to the at least one of the plurality of prior path metrics to determine the second result includes adding using modulo arithmetic.

34. The method of claim 33, wherein the plurality of branch metrics includes a respective set of branch metrics for each set of received values of the plurality of encoded signals.

35. The method of claim 34, wherein each respective set of branch metrics represents a set of probabilities that the current set of received values of the plurality of encoded signals corresponds to a respective four hypothesis input signal values.

36. The method of claim 32, wherein determining the plurality of branch metrics includes:
determining the plurality of branch metrics by processing a first and second received values of the current set of received values of the soft decision encoded signals separately from a third and fourth received values of the current set of received values of the soft decision encoded signals; and
combining a first result of processing the first and second received values with a second result of processing the third and fourth received values.

37. The method of claim 36, wherein the first result includes four intermediate branch metrics, the second result includes four intermediate branch metrics, and each respective set of branch metrics includes sixteen branch metrics.

38. The method of claim 37, wherein each branch metric of the plurality of branch metrics includes a five bit value.

39. The method of claim 32, wherein the multi-stage Viterbi decoding comprises:
storing the plurality of pairs of current trace bits and sets of previously determined trace bits corresponding to prior sets of values of the plurality of encoded input signals; and
determining the probable decoded signal based, at least in part, on the stored current and previously determined trace bits.

40. The method of claim 39, wherein determining the probable decoded signal comprises:
determining a sequence of hypothesis states based, at least in part, on the stored current and previously determined trace bits; and
determining a set of values of the probable decoded signal based on the sequence of hypothesis states.
